(19) United States
(12) Patent Application Publication
(10) Pub. No.: US 2026/0247828 A1
(43) Pub. Date: Aug. 20, 2026

(54) BEHIND DISPLAY PROJECTION AND DEVICE THEREFOR

(71) Applicants: ams-OSRAM Asia Pacific Pte. Ltd., Singapore (SG); ams International AG, Jona (CH)

(72) Inventors: Giacomo COLZI, Rüschlikon (CH); Nicolino STASIO, Zuerich (CH); David STOPPA, Adliswil (CH)

(21) Appl. No.: 18/874,592

(22) PCT Filed: Jun. 23, 2023
(86) PCT No.: PCT/EP2023/067116

§ 371 Date: Dec. 13, 2024

(30) Foreign Application Priority Data
Jun. 29, 2022 (DE) 10 2022 116 210.9

(51) Int. Cl. H10K 59/70; H10K 59/65; H10K 59/80; H10K 59/95

(52) U.S. Cl. CPC H10K 59/70; H10K 59/65; H10K 59/879; H10K 59/8792; H10K 59/95

(57) ABSTRACT

A display includes a plurality of first light sources arranged in a first region; a plurality of lenses arranged in a second region over the first region; a plurality of opaque areas and a plurality of light transmissive areas arranged in a third region over the second region. Each light source of the plurality of first light sources is configured to direct light onto a lens of the plurality of lenses and each lens of the plurality of lenses is configured to receive light from a first light source of the plurality of first light sources and to direct the light through a light transmissive area of the plurality of light transmissive areas.

### CROSS-REFERENCE TO RELATED APPLICATIONS

This application is a US National Stage application, filed under 35 U.S.C. § 371, of International Application PCT/EP2023/067116, filed on Jun. 23, 2023, and claims priority to German application 10 2022 116 210.9, filed on Jun. 29, 2022, the entirety of the above listed applications are incorporated herein by reference.

### TECHNICAL FIELD

Various aspects of this disclosure generally relate to organic light emitting diodes (OLED) and the projection of light through light transmissive regions between OLEDs.

### BACKGROUND

OLED-based displays are widely used in a variety of portable electronic devices (e.g., smartphones, tablet computers, etc.). Many such devices perform various 3D sensing operations in which the device projects a pattern onto an object, an image of the object with the projected pattern is captured, and 3D information about the object is generated based at least on distortion of the projected pattern on the object's surface. For example, many smartphones and tablet computers include a face recognition capability, in which a pattern is projected onto the user's face (e.g. in the non-visible spectrum) and the corresponding pattern distortions permit the generation of depth information. Because the 3D information (e.g. depth information) associated with a user's face may be unique to that user, such face recognition procedures may enhance security by permitting the authentication of a user.

Conventionally, user devices that utilize such pattern recognition technology (for example, face recognition technology) place their light sources for the projection of their patterns in a designated region of the display, adjacent to the OLED pixels. In many devices, the display may include a recessed (e.g. a cut-out) region to accommodate the light sources for the projected image. This is depicted in FIG. 1, which shows a smart phone in which the usable area of the display is depicted as 102, and the display includes a cutout 104, in which the projector 106 is placed. This results in a functional reduction of the overall display size and may diminish user satisfaction.

Projection through the OLED display (e.g. projection of the pattern for 3D recognition) would eliminate the need for a cutout 104 as depicted in FIG. 1; however, many aspects of the OLED display are functionally opaque in block a significant portion of light projected from behind the OLED display.

Kim et al., US 2021/0151511 A1, discloses obtaining information corresponding to a fingerprint through an OLED display.

Stasio, et al., WO 2020/256634 A1, discloses projection through an OLED display.

Rossi, et al., U.S. Pat. No. 9,273,846, discloses use of light sources and micro lens arrays (MLA) to generate structured light patterns.

Sakaguchi et al., U.S. Pat. No. 7,167,306, discloses a light transmissive display.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1 depicts a user device with a display cutout;

FIG. 2 depicts a display of a user device according to an aspect of the disclosure;

FIG. 3 depicts a pixel structure of a portion of the display;

FIG. 4 depicts an additional representation of the pixel structure;

FIG. 5 depicts an optional aspect of the disclosure, in which an optical via 502 is placed along a z-axis;

FIG. 6 depicts an optional configuration, according to an aspect of the disclosure;

FIG. 7 depicts an optional configuration in which light passing through the third region is received in one or more optical vias;

FIG. 8 depicts an optional configuration in which the light sources are configured for flood illumination;

FIG. 9 depicts a display configured as a heterogeneous display; and

FIG. 10 depicts a method of manufacturing a display.

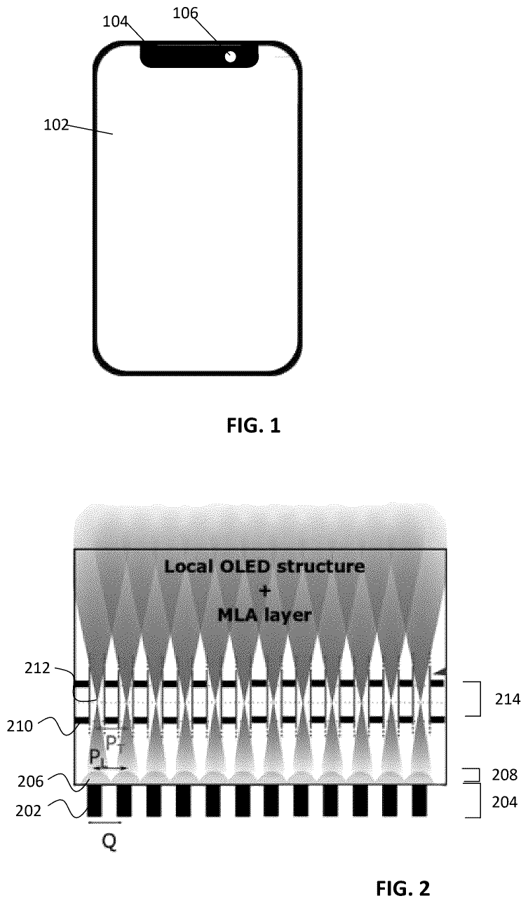

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

Various aspects of the disclosure relate to organic light-emitting diodes (OLED). OLEDs are light emitting diodes (LED), which use an organic compound in an electroluminescent process to emit light. Each OLED element may be situated between two electrodes, which may provide a current or voltage to drive the OLED and excite the organic compound to emit light. OLEDs may be formed using any of a wide variety of organic compounds. In some implementations, some of the OLED structure may be transparent. OLEDs are generally known in the art, and the princples and method disclosed herein are believed to be able to be implemented with most or all OLED configurations.

FIG. 2 depicts a portion of a display that includes a plurality of first light sources 202, arranged in a first region 204. The first region 204 may be understood as a plane along an x-axis and y-axis. Alternatively or additionally, the first region 204 may be understood as also including a height or thickness along a z-axis. The display further includes a plurality of lenses 206, arranged in a second region 208, over the first region 204. Similar to the first region 204, the second region 208 may be understood as a plane along an x-axis and y-axis. Alternatively or additionally, the second region 208 may be understood as also including a height or thickness along a z-axis. The second region 208 may be, or may essentially be, parallel to the first region 204. The distance between the plurality of first light sources 202 and the lenses 206 (or correspondingly the distance between the first region 204 and the second region 208) may by selected or determined to ensure formation of a far field high-contrast pattern (e.g. as needed to generate a dot pattern without the use of secondary MLAs). The display may further include a plurality of opaque areas 210 and a plurality of light transmissive areas 212, arranged in a third region 214, over the second region 208. The light transmissive areas may include areas of the OLED structure/lattice in which no organic compound is present (e.g. gaps between areas of the organic compound), areas with a transparent electrode, or otherwise. The plurality of opaque areas may include areas that include the organic compound, opaque electrodes, or otherwise. The third region 214 may also be along an x-axis and y-axis with an optional z-axis height. The third region 214 may be, or essentially be, parallel to the first region 204 and the second region 208. Each light source of the plurality of first light sources 202 may be configured to direct light onto a lens of the plurality of lenses 206. Each lens of the plurality of lenses 206 may be configured to receive light from a first light source of the plurality of first light sources 202 and to direct the light through a light transmissive area of the plurality of light transmissive areas 212.

FIG. 3 depicts a pixel structure of a portion of the display, including OLED layers and thin film transistor (TFT) layers. The display may include a plurality of pixels 302 (which may also be referred to herein as “second light sources”), wherein each pixel 302 includes at least a pixel light-blocking electrode 304, one or more interlayer materials 306, and a TFT light-blocking electrode 308. The TFT region may include a light-sensitive region 310. Any of the pixel light blocking electrodes and/or the TFT light-blocking electrodes may be covered with a light absorbing material 312a, 312b.

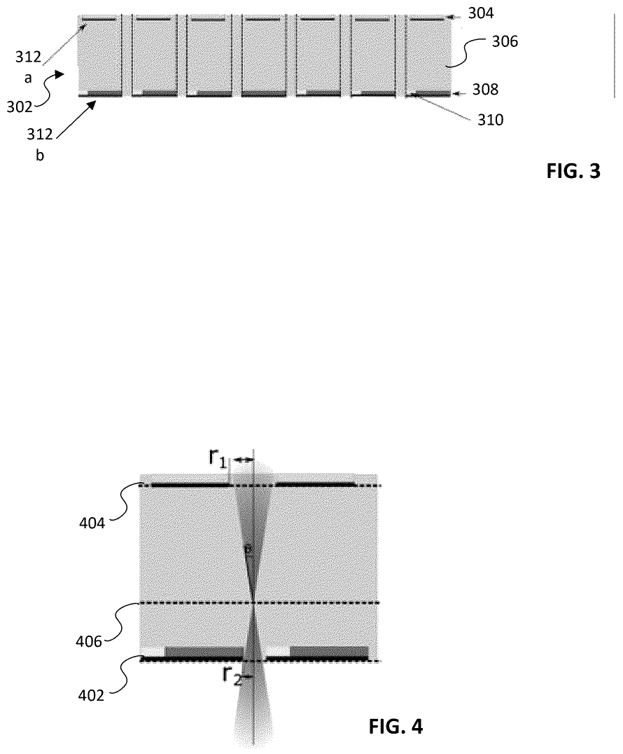

FIG. 4 depicts an additional representation of the pixel structure. In this figure, the pixel includes a TFT plane 402, a pixel electrode plane 404, and an optimal focus plane 406 between the TFT plane 402 and the pixel electrode plane 404. The light from the first light source(s) 202 passes through one or more lenses 206 of a lens array and is focused such that its point of focus is at the optimal focus plane 406 and consequently that its beam is sufficiently narrowly focused such that much or all of the beam passes through the opening through the TFT plane 402 and also through the opening in the pixel electrode plane 404.

Otherwise stated, the opening in the TFT plane 402 may not be the same size (e.g. may have a different width and/or length, such as along the x-axis and/or y-axis) as the opening in the pixel electrode plane 404. The relative height of the optimal focus plane 406 (e.g. the distance of the optical focus plane from the TFT plane and/or the distance of the optical focus plane from the pixel electrode plane) may be selected to ensure that maximum light travels through both the opening in the TFT plane 402 and the opening in the pixel electrode plane 404. This relative height of the optical focus plane 406 may be controlled, for example, by a distance between the first light sources 202 and the one or more lenses 206.

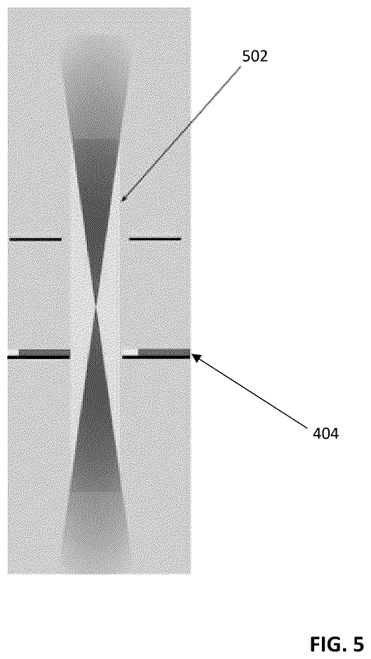

FIG. 5 depicts an optional aspect of the disclosure, in which an optical via 502 is placed along a z-axis (e.g. essentially perpendicular to the pixel electrode plane 404). An optical via may be or include an optical waveguide that it is configured to guide light through one or more layers of a device, such as a semiconductor or integrated circuit. In this manner, the lenses 206 may focus the light from the first light source 202 onto a receiving area of the optical via 502, thereby causing the light to be guided through the optical via and to exit out of an opposite side of the optical via. In this manner, the light can be conveniently directed through the pixel electrode plane 404. Alternatively or additionally, the optical via may not be a waveguide, per se, but may be or comprise a high optical quality material. In this configuration, the high optical quality material may extend from the TFT plane 402 through the pixel electrode plane 404.

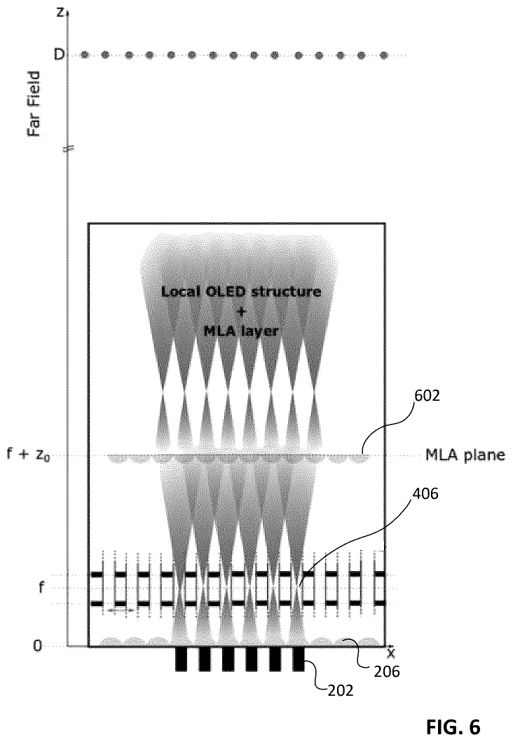

FIG. 6 depicts an optional configuration, according to an aspect of the disclosure, in which the plurality of lenses 206 is a first plurality of lenses, and in which the display includes a second plurality of lenses 602. The second plurality of lenses 602 may, for example, be or include a lens array (e.g. a micro lens array). Depending on the distance between the second plurality of lenses 602 and the optical focus plane 406, each lens of the second plurality of lenses 602 may be configured to receive light from one or more lenses of the first plurality of lenses 206. In this configuration, the first plurality of lenses 206 may form the light from the first light sources 202 into the optimal focal plane, which may increase overall transmission through the third region 214. As described above with respect to FIG. 2, the distance between the optical focal plane 406 and the second plurality of lenses 602 can be selected to ensure formation of, or control, the far field pattern.

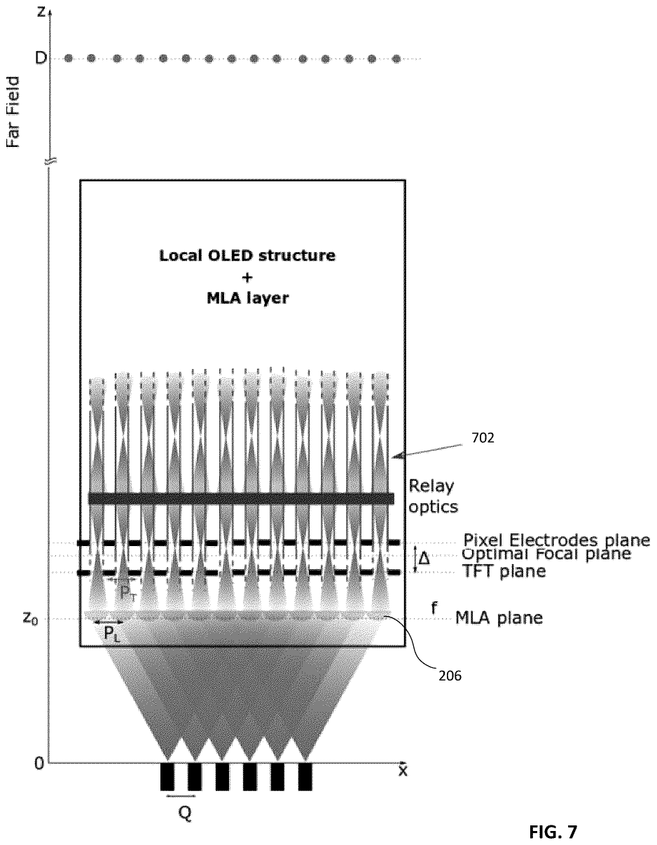

FIG. 7 depicts an optional configuration, according to an aspect of the disclosure, in which light passing through the third region 214 is received in one or more optical vias 502 and passes through one or more optical relays. In addition to the dot projector otherwise disclosed herein, this aspect of the disclosure may relate to illumination such as, for example, behind display flood illumination, which may not require the plurality of lenses 206 to eb distanced from the source plane (e.g. the first region 204) by a specific distance. That is, the field of illumination may be changed by changing the focal plane distance and the position of the first light sources 202 and the plurality of lenses 206. In this configuration, the first plurality of lenses 206 may be located in close proximity to the source plane (e.g. the first region 204), wherein, for example, the first plurality of lenses 206 is located directly on, or very close to, the first light sources 202. In configurations in which a gap is present between the first light sources 202 and the first plurality of lenses 206, the gap may be configured such that light from only one first light source 202 enters a lens of the plurality of lenses 206. This configuration may have the advantage of creating an especially compact design. Alternatively or additionally, a compact form factor may also be achieved by limiting the length of the optical vias so that they are limited the necessary length to propagate the light from the first light sources through the pixel electrodes.

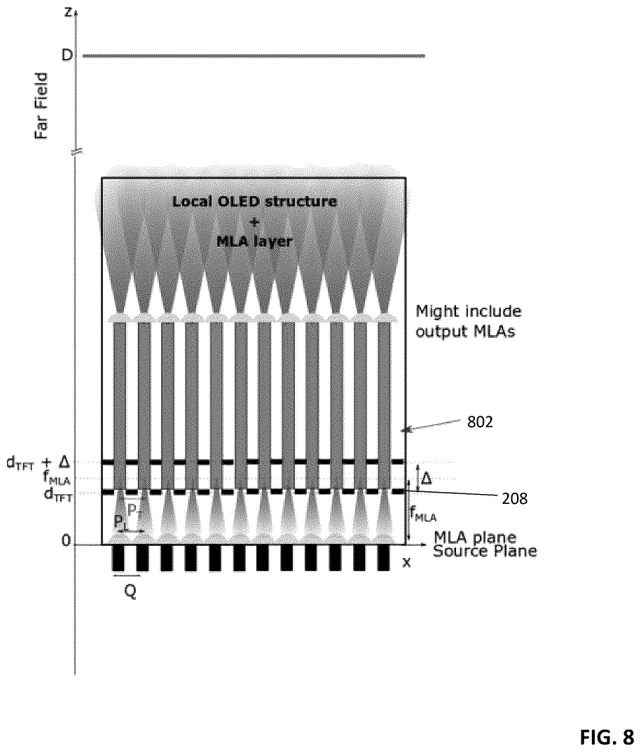

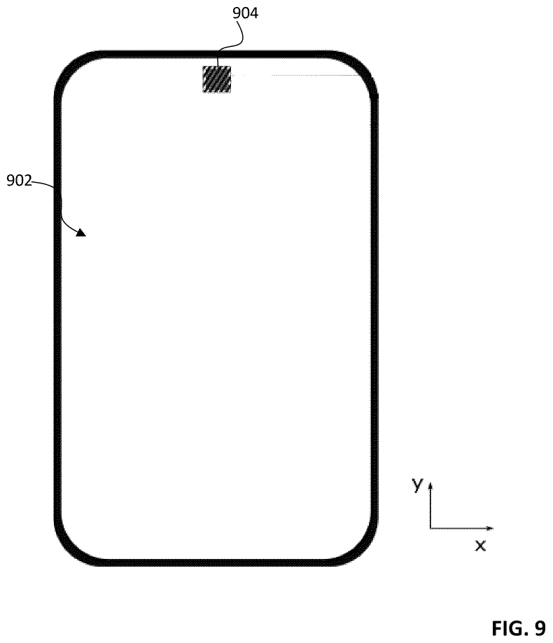

FIG. 8 depicts an optional configuration, according to an aspect of the disclosure, in which the light sources are configured for flood illumination. In this configuration, and after the light from the plurality of lenses 206 passes through the third region 214, the light may be conveyed via a plurality of high numerical aperture (NA) optical vias (e. g optical waveguides) 802. These high NA optical vias 802 may be configured to transmit most or all of light received from a first end to a second and, such as by means of total internal reflection. The high NA optical vias 802 may be optionally cladded, such as to increase internal reflection.

FIG. 9 depicts a display configured as a heterogeneous display. In this configuration, the heterogeneous display includes a first resolution area 902 and a second resolution area 904, wherein the second resolution area 904 has a lower display resolution than the first resolution area 902. Display technology is rapidly evolving, and the pitch of the display pixels and the amount of light transmissive area (e.g. 212, not depicted in this image) adjacent to the pixels may vary widely, such as between different resolutions, generation of display, and manufacturing precision. With some high-resolution displays, it is conceivable that the amount of light that can be focused and channeled through the light transmissive areas between pixels, as described herein, may be insufficient for particular purposes. In such circumstances, or in other circumstances as desired, it may be beneficial to implement a display having two or more resolution areas. Such a two-resolution-area heterogeneous display is depicted in FIG. 9 in which a high-resolution area 902 accounts for some or most of the display, but a low resolution area (an area having a resolution lower than the high-resolution area) 904 is utilized for the portions of the display through which light generated by the first light sources 202 (not depicted in this figure) is directed according to the principles and methods disclosed herein. That is, in many configurations in which it is desired or beneficial to direct the first light source 202 light through the third region 214, it may only be necessary to do so in a small portion of the display. Accordingly, a small portion of the display may be dedicated for this purpose and may be given a lower resolution than a remainder of the display, wherein the lower resolution has a greater pitch between pixels, and therefore larger light transmissive areas 212 through which the light may be directed. This may result in a greater amount of light being directed through the pixels using the principles and methods disclosed herein and/or more generous manufacturing tolerances.

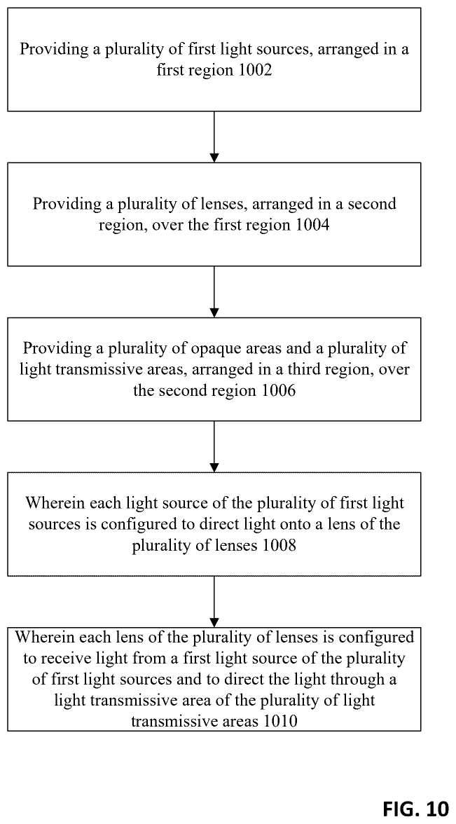

FIG. 10 depicts a method of manufacturing a display including providing a plurality of first light sources, arranged in a first region 1002; providing a plurality of lenses, arranged in a second region, over the first region 1004; providing a plurality of opaque areas and a plurality of light transmissive areas, arranged in a third region, over the second region 1006; wherein each light source of the plurality of first light sources is configured to direct light onto a lens of the plurality of lenses 1008; and wherein each lens of the plurality of lenses is configured to receive light from a first light source of the plurality of first light sources and to direct the light through a light transmissive area of the plurality of light transmissive areas 1010.

According to an aspect of the disclosure, the structures disclosed herein may be configured as a display 102, wherein the display 102 includes a plurality of first light sources 202, arranged in a first region 204. The plurality of first light sources 202 may be or include any light generating elements. According to an aspect of the disclosure, the plurality of first light sources 202 may be vertical cavity surface emitting lasers.

The display may further include a plurality of lenses 206, which may be arranged in a second region 208, over the first region 204. The plurality of lenses 206 may be configured to receive light from the plurality of first light sources 202 and direct the light to a third region 214. The plurality of lenses 206 may optionally be a microlens array. The microlens array may include a plurality of microlenses, arranged in a periodic pattern (e.g. a square pattern, a hexagonal pattern, etc.). The microlens array may be configured to have a particularly small pitch between the micro lenses. According to an aspect of the disclosure, the pitch may optionally be less than 500 μm; the pitch may optionally be less than 200 μm; the pitch may optionally be less than 100 μm; the pitch may optionally be less than 50 μm; or the pitch may optionally be less than 10 μm.

Each lens of the plurality of lenses 206 may be configured to receive light from one, or more than one, light source of the first light sources 202. That is, in some circumstances, it may be desirable to configure the plurality of lenses 206 such that they receive light from multiple light sources of the plurality of first light sources 202. Alternatively, the plurality of lenses 206 may be configured such that each lens of the plurality of lenses 206 receive light from a single first light source of the plurality of first light sources 202.

The display may include a plurality of opaque areas 210 and a plurality of light transmissive areas 212, arranged in the third region 214, over the second region 208. The plurality of opaque areas 210 and the plurality of light transmissive areas 212 may be the opaque areas and the light transmissive areas of a plurality of pixels 302. In this manner, the opaque areas 210 may correspond to one or more light emitting diodes of the pixels (e.g. electrodes, organic compounds, semiconductors, etc.), and the light transmissive areas 212 may correspond to spaces between the light emitting diodes.

The light emitting diodes may generally be organic light emitting diodes. Alternatively, in some configurations, it may be possible to optionally implement the concepts disclosed herein with a plurality of inorganic light emitting diodes. The principles and methods disclosed herein should be understood as applying to both organic light emitting diodes and inorganic light emitting diodes.

Each lens of the plurality of lenses 206 may be configured to receive light from at least one first light source of the plurality of first light sources 202 and to direct the light through a light transmissive area of the plurality of light transmissive areas 212 within the third region 214. The plurality of light transmissive areas 212 may be areas between the second light sources 302. Each lens of the plurality of lenses 206 may have a refraction characteristic and a distance to the light transmissive area of the plurality of light transmissive areas 212 such that the each lens of the plurality of lenses 206 refracts light from the first light source of the plurality of first light sources 202 to have a focal point in a light transmissive area 212 of the plurality of light transmissive areas 212 based on the refraction characteristic and the distance to the light transmissive area 212.

The display may further include a controller, which may be configured to control the plurality of second light sources 302 to emit an image on the display. The controller may be any processor or processors which may be capable of controlling at least a plurality of second light sources 302.

The plurality of first light sources 202 may be optionally arranged for the projection of a test pattern onto a surface exterior to the display. This may be particularly useful in determination of three-dimensional information about an object from an image. Using this technique, a pattern is projected onto an object, and an image is taken of the pattern as projected upon the object. The pattern will become distorted based on the distance between the light source for the projection and the instantaneous portion of the object onto which the pattern is projected. By analyzing the distortions in the pattern, information about the depth of the given portion of the object relative to the projection source may be obtained. This may be, for example, a valuable technique for face recognition. According to an aspect of the disclosure, the principles and methods disclosed herein may be utilized in face recognition processing.

The display may optionally include one or more optical vias. In such configurations, each optical via of the plurality of optical vias may be arranged within a light transmissive area of the plurality of light transmissive areas. Illustratively, the plurality of second light sources may be arranged along an x-axis and y-axis, and the optical vias may be arranged along a z-axis, such that the optical vias are essentially perpendicular to a plane including the second light sources. Each optical via of the plurality of optical vias may include a first end and a second end, opposite the first end. The optical vias may be configured to receive at their first end light emitted from one or more lenses of the first plurality of lenses and to emit the light from its second end.

Each second light source of the plurality of second light sources may be described by a first side and a second side, opposite the first side. In implementations in which the second plurality of lenses is present, the first side may face the second plurality of lenses. As an alternative descriptive method, the second side may be understood as the side that faces the first plurality of lenses. The second side may include a plurality of light absorbing areas surrounding the light transmissive areas, wherein the plurality of light absorbing areas is configured to absorb light from the plurality of first light sources.

In some configurations, there may be an optional second array of lenses over the secondary light sources. In this manner, the output of the second light sources can be collimated by a third set of lenses. The collimated light travels from the collimating lenses over the second light sources and to the second array of lenses. In this manner, the second array of lenses acts as a diffusor.

Additional aspects of the disclosure will be described by way of examples.

In Example 1, a display, including a plurality of first light sources, arranged in a first region; a plurality of lenses, arranged in a second region, over the first region; a plurality of opaque areas and a plurality of light transmissive areas, arranged in a third region, over the second region; wherein each light source of the plurality of first light sources is configured to direct light onto a lens of the plurality of lenses; wherein each lens of the plurality of lenses is configured to receive light from a first light source of the plurality of first light sources and to direct the light through a light transmissive area of the plurality of light transmissive areas.

In Example 2, the display of Example 1, wherein the plurality of opaque areas is a plurality of second light sources.

In Example 3, the display of Example 2, further including a controller, configured to control the plurality of second light sources to emit an image on the display.

In Example 4, the display of Example 1 or 3, wherein the plurality of first light sources is or includes vertical cavity surface emitting lasers.

In Example 5, the display of any one of Examples 1 to 4, wherein the plurality of lenses is a plurality of lenses of a micro lens array.

In Example 6, the display of any one of Examples 1 to 5, wherein the plurality of second light sources is a plurality of organic light-emitting diodes.

In Example 7, the display of any one of Examples 1 to 5, wherein the plurality of second light sources is a plurality of inorganic light-emitting diodes.

In Example 8, the display of Example 7, wherein the display includes a plurality of pixels arranged in the third region, and wherein each pixel includes an organic light-emitting diode of the plurality of light-emitting diodes.

In Example 9, the display of any one of Examples 1 to 8, wherein each light transmissive area of the plurality of light transmissive areas is arranged between second light sources of the plurality of second light sources.

In Example 10, the display of any one of Examples 1 to 9, wherein the plurality of first light sources is arranged for projection of the test pattern onto a surface exterior to the

In Example 11, the display of any one of Examples 1 to 10, wherein each lens of the plurality of lenses is configured to receive light from a first light source of the plurality of first light sources and to emit the light toward a light transmissive area of the plurality of light transmissive areas.

In Example 12, the display of Example 11, wherein each lens of the plurality of lenses has a refraction characteristic and a distance to the light transmissive area of the plurality of light transmissive areas, and wherein the each lens of the plurality of lenses is configured to refract light from the first light source of the plurality of first light sources to have a focal point in the transmissive area of the plurality of transmissive areas based on the refraction characteristic and the distance to the light transmissive area.

In Example 13, the display of any one of Examples 1 to 12, further including a plurality of optical vias, each optical via of the plurality of optical vias being arranged within a light transmissive area of the plurality of light transmissive areas.

In Example 14, the display of Example 13, wherein each optical via of the plurality of optical vias includes a first end and a second end, opposite the first end, and is configured to receive at its first end light emitted from a lens of the first plurality of lenses and to emit the light from its second end.

In Example 15, the display of Example 13 or 14, wherein each optical via of the plurality of optical vias includes a longitudinal axis, and wherein each optical via of the plurality of optical vias intersects the third region.

In Example 16, the display of any one of Examples 1 to 15, wherein the plurality of lenses is a first plurality of lenses; wherein the display further includes a second plurality of lenses, disposed along a fourth region, over the third region.

In Example 17, the display of any one of Examples 1 to 16, wherein each second light source of the plurality of second light sources includes a first side, facing the second plurality of lenses, and a second side, opposite the first side; and wherein the second side includes a plurality of light absorbing areas surrounding the light transmissive areas; wherein the plurality of light absorbing areas are configured to absorb light from the plurality of first light sources.

In Example 18, the display of any one of Examples 1 to 16, wherein each second light source of the plurality of second light sources includes a first side, facing the second plurality of lenses, and a second side, opposite the first side; and wherein the second side includes a plurality of light reflecting areas surrounding the light transmissive areas; wherein the plurality of light reflecting areas is configured to reflect light from the plurality of first light sources.

In Example 19, the display of any one of Examples 1 to 18, wherein each light source of the plurality of first light sources is configured to direct light onto exactly one lens of the plurality of lenses.

In Example 20, the display of any one of Examples 1 to 18, wherein each light source of the plurality of first light sources is configured to direct light onto two or more lenses of the plurality of lenses.

In Example 21, a display, including a first resolution area having a first resolution, and a second resolution area, having a second resolution, different from the first resolution, wherein the second resolution area includes the elements of any one of Examples 1 to 20.

In Example 22, the display of Example 21, wherein the second resolution area has a lower resolution than the first resolution area.

In Example 23, the display of Example 21 or 22, wherein the first resolution area includes no plurality of first light sources and/or no plurality of lenses.

In Example 24, a device, including:
the display of any one of Examples 1 to 23, wherein the plurality of first light sources is arranged in a test pattern for projection of the test pattern onto a surface exterior to the display; further including an image sensor, configured to receive a reflection of the test pattern off of the surface; a processor, configured to receive from the image sensor data representing the reflection of the test pattern and to determine whether the data satisfy a predetermined condition.

In Example 25, a method of manufacturing a display, including: providing a plurality of first light sources, arranged in a first region; providing a plurality of lenses, arranged in a second region, over the first region; providing a plurality of opaque areas and a plurality of light transmissive areas, arranged in a third region, over the second region; wherein each light source of the plurality of first light sources is configured to direct light onto a lens of the plurality of lenses; and wherein each lens of the plurality of lenses is configured to receive light from a first light source of the plurality of first light sources and to direct the light through a light transmissive area of the plurality of light transmissive areas.

In Example 26, the method of Example 25, wherein the plurality of opaque areas is a plurality of second light sources.

In Example 27, the method of Example 26, further controlling via a controller the plurality of second light sources to emit an image on the display.

In Example 28, the method of Example 25 or 27, wherein the plurality of first light sources is or includes vertical cavity surface emitting lasers.

In Example 29, the method of any one of Examples 25 to 28, wherein the plurality of lenses is or includes a plurality of lenses of a micro lens array.

In Example 30, the method of any one of Examples 25 to 29, wherein the plurality of second light sources is a plurality of organic light-emitting diodes.

In Example 31, the method of any one of Examples 25 to 29, wherein the plurality of second light sources is a plurality of inorganic light-emitting diodes.

In Example 32, the method of any one of Examples 25 to 31, further including arranging the plurality of first light sources for projection of the test pattern onto a surface

In Example 33, the method of any one of Examples 25 to 32, further including configuring each lens of the plurality of lenses to receive light from a first light source of the plurality of first light sources and to emit the light toward a light transmissive area of the plurality of light transmissive areas.

In Example 34, the method of Example 33, wherein each lens of the plurality of lenses has a refraction characteristic and a distance to the light transmissive area of the plurality of light transmissive areas; further including configuring the each lens of the plurality of lenses to refract light from the first light source of the plurality of first light sources to have a focal point in the transmissive area of the plurality of transmissive areas based on the refraction characteristic and the distance to the light transmissive area.

In Example 35, the method of any one of Examples 25 to 34, further including providing a plurality of optical vias such that each optical via of the plurality of optical vias is arranged within a light transmissive area of the plurality of light transmissive areas.

In Example 36, the method of Example 35, wherein each optical via includes a first end and a second end, opposite the first end; further including configuring each optical via of the plurality of optical vias to receive at its first end light emitted from a lens of the first plurality of lenses and to emit the light from its second end.

In Example 37, the method of Example 35 or 36, wherein each optical via of the plurality of optical vias includes a longitudinal axis, and wherein each optical via of the plurality of optical vias intersects the third region.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

### LIST OF REFERENCE SIGNS

102 Display
104 Recess/Cutout
106 Projector
202 First light source/first light sources
204 First region
206 Lens/plurality of lenses
208 Second region
210 Opaque area/opaque areas
212 Light transmissive area(s)
214 Third region
302 Pixel(s)/Second light sources
304 Pixel light-blocking electrode(s)
306 Interlayer materials
308 TFT light-blocking electrode(s) 308
310 Light-sensitive region
312a, 312b Light absorbing material
402 TFT Plane
404 Pixel electrode plane
406 optimal focus plane
502 optical via/optical vias
602 Second plurality of lenses
702 Optical relay/optical relays
802 High numerical aperture optical via(s)
902 First resolution area
904 Second resolution area

What is claimed is:

1. A display comprising:
a plurality of first light sources arranged in a first region;
a plurality of lenses arranged in a second region over the first region a plurality of opaque areas and a plurality of light transmissive areas arranged in a third region over the second region;
wherein each light source of the plurality of first light sources is configured to direct light onto a lens of the plurality of lenses
wherein each lens of the plurality of lenses is configured to receive light from a first light source of the plurality of first light sources and to direct the light through a light transmissive area of the plurality of light transmissive areas;
wherein the plurality of opaque areas are a plurality of second light sources wherein each lens of the plurality of lenses is configured to receive light from a first light source of the plurality of first light sources and to emit the light toward a light transmissive area of the plurality of light transmissive areas;
wherein each lens of the plurality of lenses has a refraction characteristic and a distance to the light transmissive area of the plurality of light transmissive areas and
wherein the each lens of the plurality of lenses is configured to refract light from the first light source of the plurality of first light sources to have a focal point in the transmissive area of the plurality of light transmissive areas based on the refraction characteristic and the distance to the light transmissive area.

2. The display of claim 1, further comprising a controller, configured to control the plurality of second light sources to emit an image on the display.

3. The display of claim 1, wherein the plurality of first light sources is a plurality of vertical cavity surface emitting lasers.

4. The display of claim 1, wherein the plurality of lenses is a plurality of lenses of a micro lens array.

5. The display of claim 1, wherein the plurality of second light sources is a plurality of organic light-emitting diodes.

6. The display of claim 5, wherein the display comprises a plurality of pixels arranged in the third region, and wherein each pixel comprises an organic light-emitting diode of the plurality of organic light-emitting diodes.

7. The display of claim 1, wherein each light transmissive area of the plurality of light transmissive areas is arranged between second light sources of the plurality of second light sources.

8. The display of claim 1, wherein the plurality of first light sources is arranged for projection of a test pattern onto a surface exterior to the display.

9. The display of claim 1, further comprising a plurality of optical vias, each optical via of the plurality of optical vias being arranged within a light transmissive area of the plurality of light transmissive areas.

10. The display of claim 1, wherein the plurality of lenses is a first plurality of lenses wherein the display further comprising a second plurality of lenses, disposed along a fourth region, over the third region.

11. The display of claim 1, wherein each second light source of the plurality of second light sources comprises a first side, facing the second plurality of lenses, and a second side, opposite the first side; and wherein the second side comprises a plurality of light absorbing areas surrounding the light transmissive areas; wherein the plurality of light absorbing areas are configured to absorb light from the plurality of first light sources.

12. The display of claim 1, wherein each second light source of the plurality of second light sources comprises a first side, facing the second plurality of lenses, and a second side, opposite the first side; and wherein the second side comprises a plurality of light reflecting areas surrounding the light transmissive areas; wherein the plurality of light reflecting areas is configured to reflect light from the plurality of first light sources.

13. The display of claim 1, wherein each light source of the plurality of first light sources is configured to direct light onto exactly one lens of the plurality of lenses.

14. The display of claim 1, wherein each light source of the plurality of first light sources is configured to direct light onto two or more lenses of the plurality of lenses.

15. A display, comprising a first resolution area having a first resolution, and a second resolution area, having a second resolution, different from the first resolution, wherein the second resolution area comprises the elements of claim 1, wherein the second resolution area has a lower resolution than the first resolution area.

16. A method of manufacturing a display, comprising:
providing a plurality of first light sources, arranged in a first region;
providing a plurality of lenses, arranged in a second region, over the first region;
providing a plurality of opaque areas and a plurality of light transmissive areas, arranged in a third region, over the second region;
wherein each light source of the plurality of first light sources is configured to direct light onto a lens of the plurality of lenses;
wherein each lens of the plurality of lenses is configured to receive light from a first light source of the plurality of first light sources and to direct the light through a light transmissive area of the plurality of light transmissive areas;
wherein each lens of the plurality of lenses is configured to receive light from a first light source of the plurality of first light sources and to direct the light through a light transmissive area of the plurality of light transmissive areas;
wherein each lens of the plurality of lenses has a refraction characteristic and a distance to the light transmissive area of the plurality of light transmissive areas; and
wherein the each lens of the plurality of lenses is configured to refract light from the first light source of the plurality of first light sources to have a focal point in the transmissive area of the plurality of light transmissive areas based on the refraction characteristic and the distance to the light transmissive area.
